(19) United States
(12) Patent Application Publication
(10) Pub. No.: US 2006/0249760 A1
(43) Pub. Date: Nov. 9, 2006

(54) HIGH-VOLTAGE TRANSISTOR OF SEMICONDUCTOR DEVICE AND METHOD OF FORMING THE SAME

(75) Inventors: Gyoung-Ho Buh, Gyeonggi-do, (KR); Yu-Gyun Shin, Gyeonggi-do (KR); Tai-Su Park, Gyeonggi-do, (KR); Jin-Wook LEE, Gyeonggi-do, (KR); Guk-Hyon Yon, Gyeonggi-do, (KR)

Correspondence Address: MARGER JOHNSON & MCCOLLOM, P.C., 210 SW MORRISON STREET, SUITE 400, PORTLAND, OR, 97204, US

(73) Assignee: Samsung Electronics Co., Ltd., Gyeonggi-Do (KR)

(21) Appl. No.: 11/379,206

(22) Filed: Apr. 18, 2006

(30) Foreign Application Priority Data
Apr. 18, 2005 (KR) 10-2005-0032008

(51) Int. Cl. H01L 29/772; H01L 21/336

(52) U.S. Cl. 257/288; 257/404; 438/289; 438/286

(57) ABSTRACT

There are provided a high-voltage transistor and a method of forming the same. A channel region of the high-voltage transistor includes a first region and a second region. The first region has high impurity concentration that is higher than that of the second region. In addition, the first region may be in contact with the isolation layer. Thus, it is possible to enhance leakage current characteristics of the high-voltage transistor.

### BACKGROUND

This application claims the benefit of Korean Patent Application No. 2005-32008, filed Apr. 18, 2005, the contents of which are hereby incorporated herein by reference in their entirety.

1. Field of the Invention

The present invention relates to a semiconductor device and a method of forming the same, and more particularly, to a high-voltage transistor of a semiconductor device and a method of forming the same.

2. Description of the Related Art

Generally, among various field effect transistors of a semiconductor device, there is a high-voltage field effect transistor (hereinafter, referred to as a high-voltage transistor) to which a high voltage is applied. The high-voltage transistor may be used for an electrically erasable and programmable read only memory (EEPROM) device requiring a high voltage for electrically writing/erasing data in/from each memory cell, semiconductor devices which are operated by an external high voltage, and so forth. Typically, high-voltage transistors need to have excellent durability because of the high voltage applied to them. Furthermore, there is a special concern about leakage current characteristics in the high-voltage transistor again because of the relatively high voltage.

FIG. 1A is a plane view of a conventional high-voltage transistor, and FIGS. 1B and 1C are cross-sectional views taken along the line I-I′ and the line II-II′ of FIG. 1A, respectively.

Referring to FIGS. 1A to 1C, a trench 2 is formed to define an active region A by etching a predetermined region of a semiconductor substrate 1. The trench 2 is filled with a predetermined material to form an isolation layer 3. A gate electrode 5 is disposed over the semiconductor substrate 1 such that it crosses over the active region A, and a gate oxide layer 4 is interposed between the gate electrode 5 and the active region A.

A source region 6s is formed in the active region A at one side of the gate electrode 5, and a drain region 6d is formed in the active region A at the other side of the gate electrode 5, which is opposite to the source region 6s. The gate electrode 5, the source region 6s, and the drain region 6d constitute a high-voltage transistor.

A channel region defined under the gate electrode 5 is doped with a first conductive impurity, and the source and drain regions 6s and 6d are doped with a second conductive impurity. Thus, the channel region and the source/drain regions 6s and 6d constitute a PN junction.

Because a high voltage is applied to the high-voltage transistor, the gate oxide layer 4 may be damaged, or a leakage current may flow from the gate electrode 5 to the channel region through the gate oxide layer 4. In order to address these problems, the gate oxide layer 4 may be formed considerably thicker in the high voltage transistor as compared to general transistors, such as a low-voltage transistor or the like.

In addition, the characteristics of the junction leakage current may be deteriorated between the channel region and at least one of the source/drain regions 6s and 6d due to the high voltage applied to the high-voltage transistor. To overcome these problems, the channel region can have a very low impurity concentration. Moreover, the source/drain regions 6s and 6d may also have low impurity concentrations.

However, lowering the impurity concentration of p-type and n-type semiconductors constituting the p-n junction increases the junction breakdown voltage of the p-n junction. This, in turn, results in a decrease in the junction leakage current between the p-type and the n-type semiconductors. Because of these reasons, the channel region is designed to have a very low impurity concentration.

In the conventional high-voltage transistor, interface states may be formed at an interface surface between the channel region and the gate oxide layer 4 due to various factors. In particular, the high-density interface states may be formed at both edges 7 of the channel region adjacent to the isolation layer 3. One of the various factors for the interface states is etch damage.

When performing an etching process for forming the trench 2, both of the edges 7 of the channel region may be damaged during the etching process. On the contrary, a central portion of the channel region is covered with a mask pattern (not shown) so that it remains relatively undamaged during the etching process. Therefore, the density of the interface states of both the edges 7 may be higher than that of the central portion.

The interface states may change the Fermi level of the channel region. Accordingly, the channel region may be changed into a depletion state or an inversion state. As the density of the interface states increases, the variation of the Fermi level may be large. Thus, the leakage current 8 may flow between the source and drain region 6s and 6d through the channel region under a state where the high-voltage transistor is turned off. In particular, the leakage current 8 may flow through both the edges 7 of the channel region having high-density interface states.

In addition, the impurity concentration of the channel region is very low in order to minimize the junction leakage current between the channel region and the source/drain regions 6s and 6d. Generally, as the impurity concentration of the channel region becomes low, the depletion or the inversion of the channel region due to the interface states may be deepened. As a result, since the impurity concentration of the channel region is extremely low, the leakage current 8 between the source and drain regions 6s and 6d may increase more and more.

### SUMMARY

The present invention provides a high-voltage transistor of a semiconductor device having enhanced leakage current characteristics, and a method of forming the same.

The present invention also provides a high-voltage transistor of a semiconductor device capable of minimizing a leakage current between a source region and a drain region through a channel region, and a method of forming the same.

The present invention further provides a high-voltage transistor of a semiconductor device capable of minimizing a junction leakage current as well as a leakage current between a source region and a drain region through a channel region, and a method of forming the same.

Embodiments of the present invention provide high-voltage transistors. The high-voltage transistors may include an isolation layer formed on a semiconductor substrate, to define an active region, and a gate electrode crossing over the active region. A gate insulating layer is interposed between the gate electrode and the active region. A source region and a drain region are disposed in the active region at both sides of the gate electrode, respectively. A channel region is defined under the gate electrode, wherein the channel region has a first region in contact with the isolation layer and a second region. An impurity concentration of the first region is higher than that of the second region.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle of the invention. In the drawings:

FIG. 1A is a plane view of a conventional high-voltage transistor;

FIGS. 1B and 1C are cross-sectional views taken along the line I-I′ and the line II-II′ of FIG. 1A, respectively;

FIG. 2A is a plane view of a high-voltage transistor according to one embodiment of the present invention;

FIGS. 2B and 2C are cross-sectional views taken along the line III-III′ and the line IV-IV′ of FIG. 2A, respectively;

FIG. 3A is a plane view of a high-voltage transistor according to another embodiment of the present invention;

FIG. 3B is a cross-sectional view taken along the line V-V′ of FIG. 3A;

FIG. 4 is a graph of a current between a source and a drain versus a gate voltage, illustrating characteristics of the high-voltage transistor according to the present invention;

FIGS. 5A to 8A are plane views illustrating a method of forming the high-voltage transistor of the semiconductor device according to the embodiments of the present invention;

FIGS. 5B to 8B are cross-sectional views taken along the lines VI-VI′ of FIGS. 5A to 8A, respectively; and

FIGS. 5C to 8C are cross-sectional views taken along the lines VII-VII′ of FIGS. 5A to 8A, respectively.

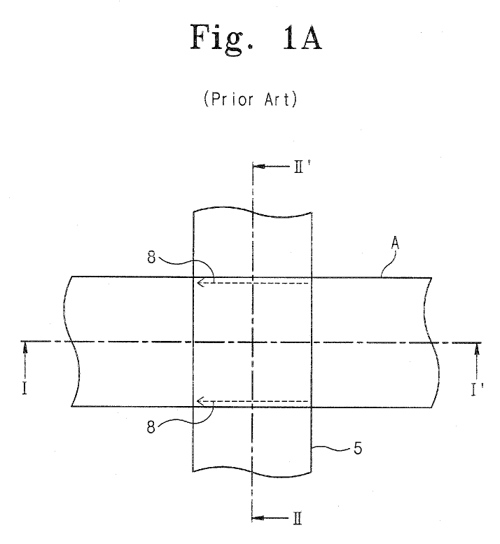

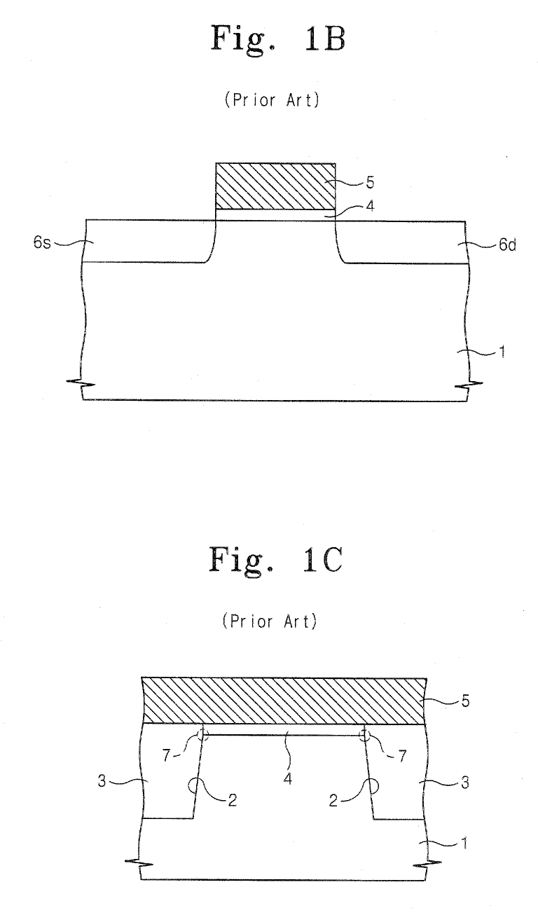

### DETAILED DESCRIPTION

Reference will now be made in detail to embodiments of the present invention, examples of which are illustrated in the accompanying drawings. However, the present invention is not limited to the embodiments illustrated herein; rather the embodiments are introduced to provide an easy and complete understanding of the scope and spirit of the present invention. In the drawings, the thicknesses of layers and regions are exaggerated for clarity. It will also be understood that when a layer is referred to as being “on” another layer or substrate, it can be directly on the other layer or substrate, or intervening layers may also be present. Like reference numerals in the drawings denote like elements, and thus their description will be omitted.

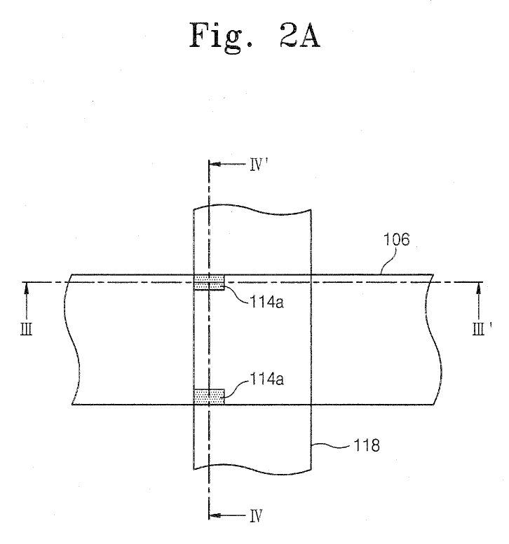

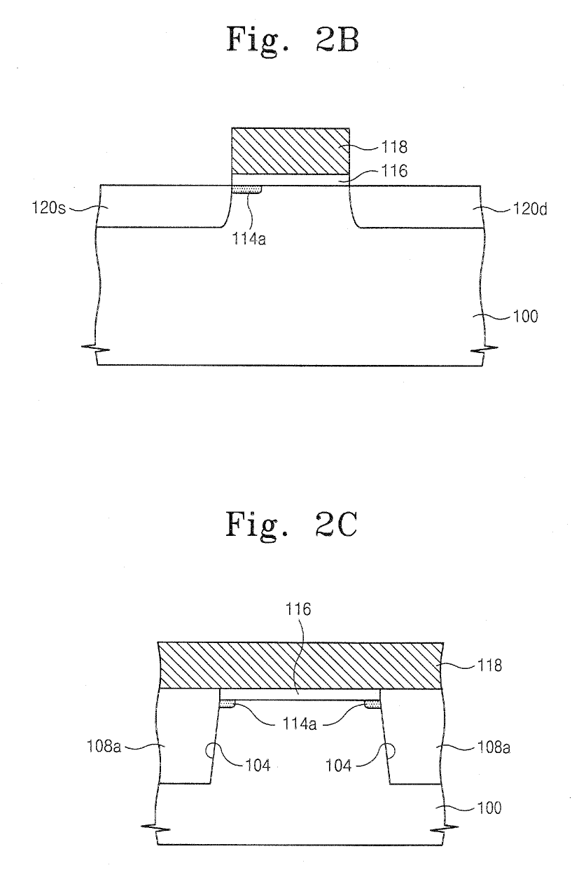

FIG. 2A is a plane view of a high-voltage transistor according to one embodiment of the present invention, and FIGS. 2B and 2C are cross-sectional views taken along line III-III′ and line IV-IV′ of FIG. 2A, respectively.

Referring to FIGS. 2A to 2C, an isolation layer 108a is disposed at a predetermined region of a semiconductor substrate 100 that is doped with first conductive impurities, to thereby define an active region 106. It is preferable that the isolation layer 108a be a trench isolation layer. That is, it is preferable that the isolation layer 108a fill a trench 104 formed in the semiconductor substrate 100.

A gate electrode 118 crosses over the active region 106. A gate insulating layer 116 is interposed between the gate electrode 118 and the active region 106. A source region 120s is disposed in the active region 106 at one side of the gate electrode 118, and a drain region 120d is disposed in the active region 106 at the other side of the gate electrode 118, which is opposite to the source region 120s. The source and drain regions 120s and 120d are doped with second conductive impurities.

Although it is not shown in the drawings, a capping insulating pattern (not shown) may be disposed on the gate electrode 118, and a gate spacer (not shown) may be disposed on both sidewalls of the gate electrode 118.

A channel region is defined at the active region 106 under the gate electrode 118. The channel region is disposed between the source and drain regions 120s and 120d. The channel region is doped with first conductive impurities. For instance, the channel region may be doped with n-type impurities and the source and drain regions 120s and 120d may be doped with p-type impurities. On the contrary, the channel region may be doped with p-type impurities and the source and drain regions 120s and 120d may be doped with n-type impurities.

The channel region has a first region 114a and a second region. Impurity concentration of the first region 114a is different from that of the second region. It is preferable that the first region 114a is in contact with the isolation layer 108a. Herein, the second region corresponds to the active region 106 under the gate electrode 118 not defined by the first region 114a.

The channel region may have a pair of first regions 114a, where the first regions 114a are spaced apart from each other. Additionally, each of the first regions 114a may be in contact with the isolation layer 108a on each side of the channel region, respectively. At least a portion of the second region is disposed between the pair of the first regions 114a.

As stated above, the first region 114a has the impurity concentration higher than that of the second region. As a result, the first region 114a minimizes the variations of the Fermi level due to interface states which may occur at an interface surface between the semiconductor substrate 100 and the gate insulating layer 116. The first region 114a is in contact with the isolation layer 108a. That is, the first region 114a is disposed at the edge of the channel region adjacent to the isolation layer 108a. The edge is a pathway of the leakage current between the source and the drain due to the high-density interface states. Accordingly, the amount of the leakage current between the source and the drain may be minimized when the high-voltage transistor is turned off. In other words, it is possible to minimize the leakage current between the source and the drain, which is a serious problem in the prior art, by blocking the pathway of the leakage current between the source and the drain by means of the first region 114a.

In addition, the channel region has the pair of the first regions 114a which are in contact with the isolation layer 108a on both sides thereof. As a result, all the pathways, i.e., both the edges of the channel region, of the leakage current between the source and the drain are blocked. At this time, the pair of the first regions 114a are spaced apart from each other. That is, between the pair of the first regions 114a, there is disposed at least a portion of the second region of which the impurity concentration is relatively low in comparison with the first region 114a. Thus, a decrease of the turn-on current of the high-voltage transistor is minimized.

It is preferable that the first region 114a be spaced apart from the drain region 120d. Therefore, the second region of which the impurity concentration is low, i.e., the lightly doped second region, is disposed between the first region 114a and the drain region 120d, and the drain region 120d is in contact with the second region. However, the first region 114a may be in contact with the source region 120s.

A back bias voltage may further be applied to the channel region. A source voltage and a drain voltage are applied to the source region 120s and the drain region 120d, respectively. At this time, it is preferable that the voltage difference between the drain voltage and the back bias voltage should be prominently higher than the voltage difference between the source voltage and the back bias voltage. Namely, a positive high voltage (in case of an NMOS transistor) or a negative high voltage (in case of a PMOS transistor) is applied to the drain region 120d. Whereas, a predetermined voltage, which is prominently lower than the high voltage, may be applied to the source region 120s. For example, the ground voltage may be applied to the source region 120s.

As described above, the drain region 120d to which the high voltage is applied is in contact with the lightly-doped second region. Therefore, the junction leakage current may be minimized between the drain region 120d and the channel region. Unlike the drain region 120d, a very low voltage, e.g., a ground voltage, is applied to the source region 120s. Therefore, although the source region 120s is in contact with the first region 114a of which the impurity concentration is high, i.e., the highly-doped first region 114a, the junction leakage current between the source region 120s and the channel region may be minimized.

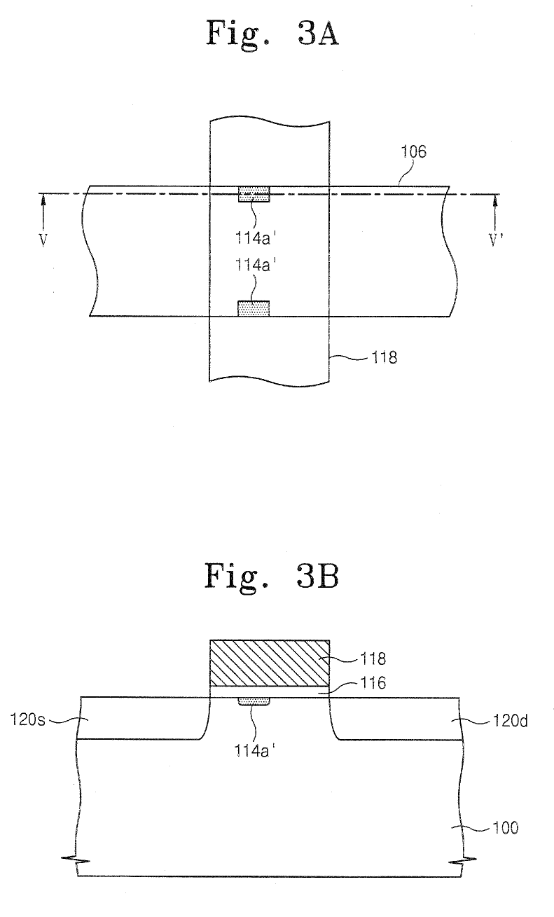

Meanwhile, the channel region may have other shapes unlike the embodiment described above, which will be illustrated with reference to FIGS. 3A and 3B. In FIGS. 3A and 3B, like reference numerals denote like elements of FIGS. 2A to 2C.

FIG. 3A is a plane view of a high-voltage transistor according to another embodiment of the present invention, and FIG. 3B is a cross-sectional view taken along the line V-V′ of FIG. 3A.

Referring to FIGS. 3A and 3B, the channel region includes a first region 114a′ and a second region. Both the first region 114a′ and the second region are doped with first conductive impurities. At this time, the first region 114a′ has the impurity concentration higher than that of the second region. A pair of first regions 114a′ may be spaced apart from each other, and may be in contact with the isolation layer 108a on both sides of the channel region, respectively. The second region may be disposed between the pair of the first regions 114a′.

The first region 114a′ may be spaced apart from the drain region 120d. As a result, the lightly doped second region may be disposed between the first region 114a′ and the drain region 120d, and the drain region 120d may be in contact with the second region. In addition, as illustrated in FIGS. 3A and 3B, the first region 114a′ may be spaced apart from the source region 120s. Therefore, the second region may also be disposed between the first region 114a′ and the source region 120s so that the source region 120s may be in contact with the lightly doped second region. That is, the first region 114a′ is spaced apart from both the source and drain regions 120s and 120d, whereby the source and drain regions 120s and 120d are in contact with the lightly doped second region. The distance between the first region 114a′ and the source region 120s may be shorter than the distance between the first region 114a′ and the drain region 120d.

The high-voltage transistor including the channel region having the first region 114a′ and the second region may achieve a similar effect as the high-voltage transistor illustrated in FIGS. 2A to 2C. That is, it may be possible to minimize the leakage current between the source and the drain when the high-voltage transistor is turned off, by blocking the pathway of the leakage current between the source and the drain by virtue of the highly-doped first region 114a′. Furthermore, since the first region 114a′ may be spaced apart from the drain region 120d, the drain region 120d may be in contact with the lightly-doped second region. Accordingly, even if the high voltage is applied to the drain region 120d, the junction leakage current between the drain region 120d and the channel region may be minimized.

In addition to this, the first region 114a′ may also be spaced apart from the source region 120s so that the source region 120s may also be in contact with the lightly doped second region. Therefore, though the high voltage is applied to the source region 120s, the junction leakage current between the source region 120s and the channel region may be minimized. As such, the high-voltage transistor including the channel region having the first region 114a′ may operate such that the turn-on current flows bidirectionally.

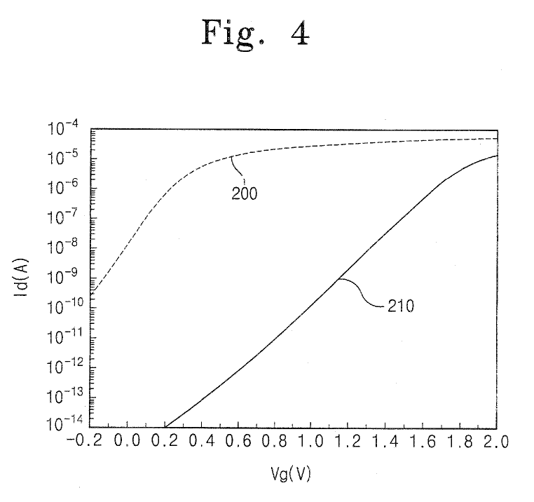

Experiments performed to check the leakage current characteristics between the source and the drain of the high-voltage transistor according to the present invention are illustrated with reference to FIG. 4.

FIG. 4 is a graph of a current between a source and a drain versus a gate voltage, illustrating characteristics of the high-voltage transistor according to the present invention.

Referring to FIG. 4, a first specimen having a first high-voltage transistor and a second specimen having a second high-voltage transistor are prepared. Both the first and second transistors are formed of NMOS transistors. The channel region of the first high-voltage transistor is doped with p-type impurities of the dose of 1×10¹⁶/cm². That is, the first high-voltage transistor corresponds to a conventional high-voltage transistor. The channel region of the second high-voltage transistor has a pair of first regions and a second region. The channel region of the second high-voltage transistor is formed as shown in FIG. 2A. That is, the second high-voltage transistor corresponds to the high-voltage transistor according to the present invention. The first region is formed by doping p-type impurities of the dose of 1×10¹⁷/cm² and the second region is formed by doping p-type impurities of the dose of 1×10¹⁶/cm². The impurity concentration of first region is thus ten times that of the second region.

The current Id between the source and the drain versus the gate voltage Vg of the conventional first high-voltage transistor is represented as a dotted line 200 in FIG. 4, whereas the current between the source and the drain versus the gate voltage of the second high-voltage transistor is represented as a solid line 210 in FIG. 4. Herein, the ground voltage is applied to all of the back bias voltage and the source voltage of the first and second transistors, and a 0.1 V drain voltage is applied to the drains of the first and second high-voltage transistors.

As illustrated in FIG. 4, when the gate voltage Vg is 0 V, i.e., in an off-state, the amount of the current Id between the source and the drain of the first conventional high-voltage transistor becomes about 10⁻⁸ A, whereas the current Id between the source and the drain of the second high-voltage transistor becomes about 0 A. In the second high-voltage transistor, when the gate voltage Vg is 2 V, the amount of the current Id between the source and the drain is measured to be about 10⁻¹⁴ A.

From these experimental data, it can be understood that the leakage current between the source and the drain of the second high-voltage transistor can be prevented by means of the first region of the channel region.

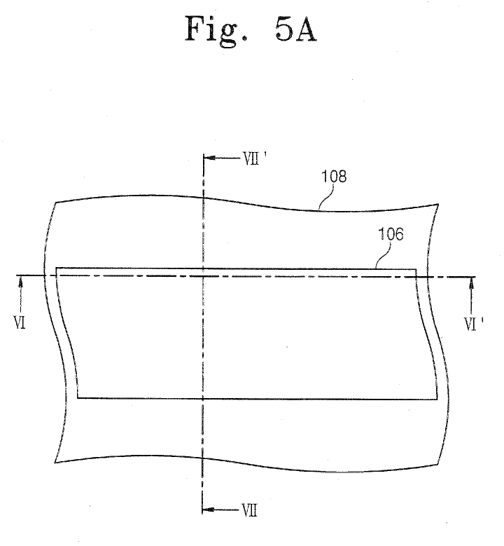

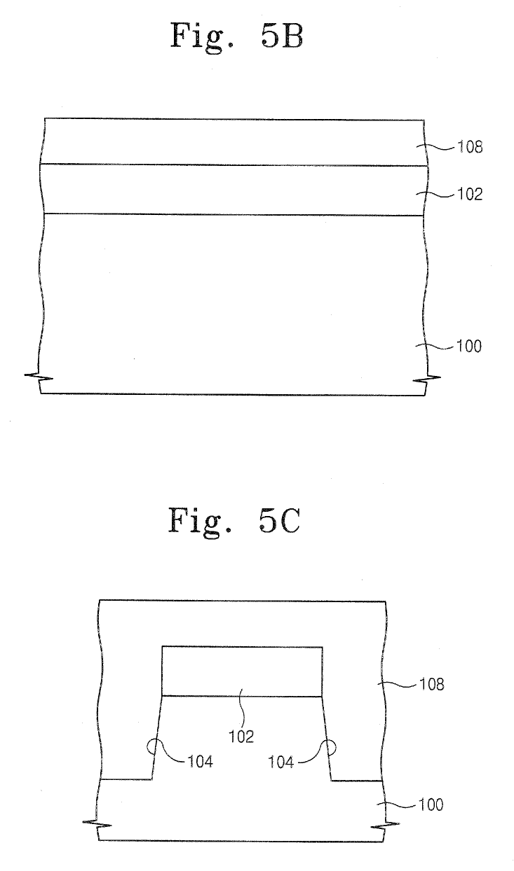

FIGS. 5A to 8A are plane views illustrating a method of forming the high-voltage transistor of the semiconductor device according to the embodiments of the present invention, and FIGS. 5B to 8B are cross-sectional views taken along the lines VI-VI′ of FIGS. 5A to 8A, respectively. Further, FIGS. 5C to 8C are cross-sectional views taken along the lines VII-VII′ of FIGS. 5A to 8A, respectively.

Referring to FIGS. 5A to 5C, a hard mask pattern 102 is formed on the semiconductor substrate 100 doped with first conductive impurities. The semiconductor substrate 100 is etched using the hard mask pattern 102 as a mask to form a trench 104 defining the active region 106. The semiconductor substrate 100 may be doped with first conductive impurities through a process of forming a well.

The hard mask pattern 102 includes a material having an etch selectivity with respect to the semiconductor substrate 100. For example, the hard mask pattern 102 may be formed of a buffer oxide layer and a silicon nitride layer stacked in sequence. The buffer oxide layer serves a role of minimizing tension stress between the silicon nitride layer and the semiconductor substrate 100.

An insulating layer 108 is formed over the entire surface of the semiconductor substrate 100 to fill the trench 104. The insulating layer 108 may include a high-density plasma oxide layer with excellent gap-fill property. In addition, the insulating layer 108 may include a thermal oxide layer formed on the sidewalls of the trench 104 before forming the high-density plasma oxide layer. Furthermore, the insulating layer 108 may include a liner layer (not shown) formed between the thermal oxide layer and the high-density plasma oxide layer.

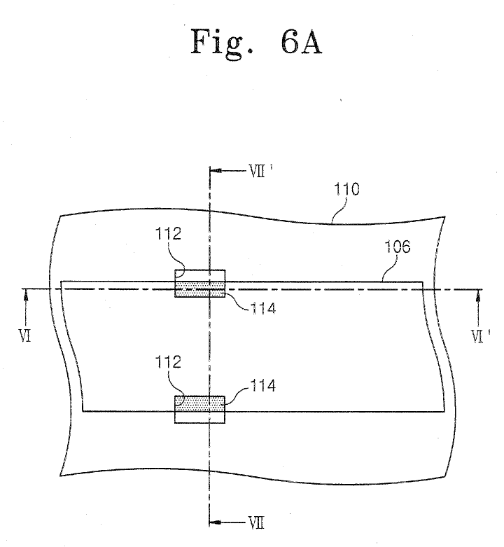

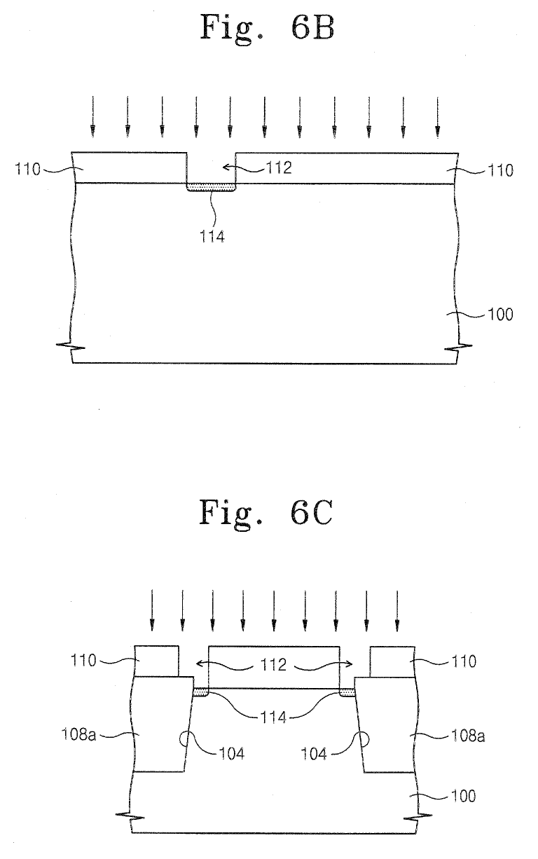

Referring to FIGS. 6A to 6C, the insulating layer 108 is planarized until the hard mask pattern 102 is exposed, to thereby form the isolation layer 108a filling the trench 104. Thereafter, the exposed hard mask pattern 102 is removed to expose the top surface of the active region 106.

A photoresist layer 110 is formed on the semiconductor substrate 100, and the photoresist layer 110 is patterned to form an opening 112 which exposes a predetermined region of the active region 106. More specifically, the opening 112 exposes the predetermined region of the active region 106 adjacent to the isolation layer 108a. The opening 112 may also expose a portion of the isolation layer 108a adjacent to the exposed active region 106.

It is preferable to form a pair of openings 112 in the photoresist layer 110. The pair of the openings 112 are spaced apart from each other so as to expose both edges of the active region 106 adjacent to the isolation layer 108a, respectively.

First conductive impurity ions are implanted to form a channel doped layer 114 using the photoresist layer 110 having the opening 112. The opening 112 exposes the portion of the isolation layer 108a adjacent to the exposed active region 106 so that the channel doped layer 114 can be in contact with the isolation layer 108a.

The channel doped layer 114 is formed by additionally implanting first conductive impurity ions into the active region 106 where first conductive impurity has been doped already. Thus, the channel doped layer 114 has the impurity concentration higher than the other regions of the active region 106. The first conductive impurity ions may be a heavy element. For instance, if the first conductive impurity ions are n-type, arsenic ions may be implanted. On the contrary, if the first conductive impurity ions are p-type, difluoroborane (BF₂) ions may be implanted. Before forming the photoresist layer 110, a buffer oxide layer (not shown) may be formed on the surface of the active region 106 for ion implantation.

Unlike the above method, after forming the channel doped layer 114 in advance, the isolation layer 108a may be formed such that the active region 106 is aligned with the channel doped layer 114. In detail, the first conductive impurity ions are selectively implanted into a predetermined region of the semiconductor substrate 100 doped with the first conductive impurities so as to form the channel doped layer 114. Afterwards, the semiconductor substrate 100 is selectively etched using the hard mask to form the trench 104 defining the active region 106. At this time, the active region 106 may include the channel doped layer 114. Thereafter, the isolation layer 108a is formed to fill the trench 104. In this embodiment, the portion of the semiconductor substrate 100 etched for forming the trench 104 may include a portion of the channel doped layer 114. Therefore, the portion of the channel doped layer 114 may be removed during the etching process for forming the trench 114. As a result, the channel doped layer 114 may be in contact with the isolation layer 108a.

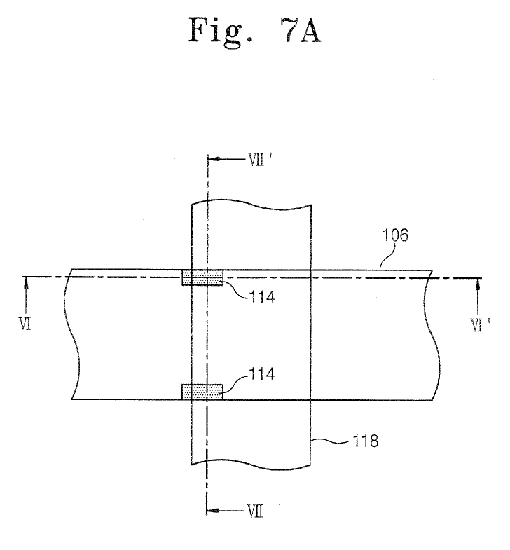

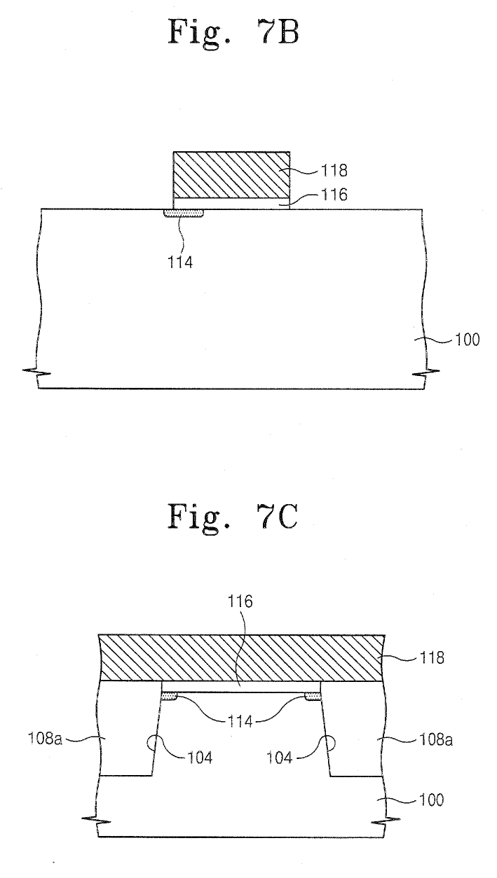

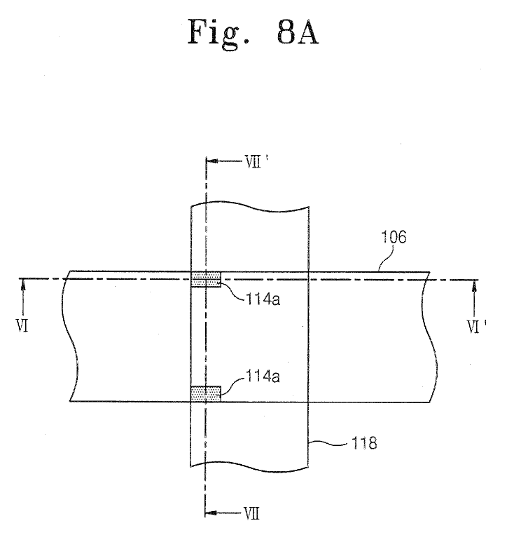

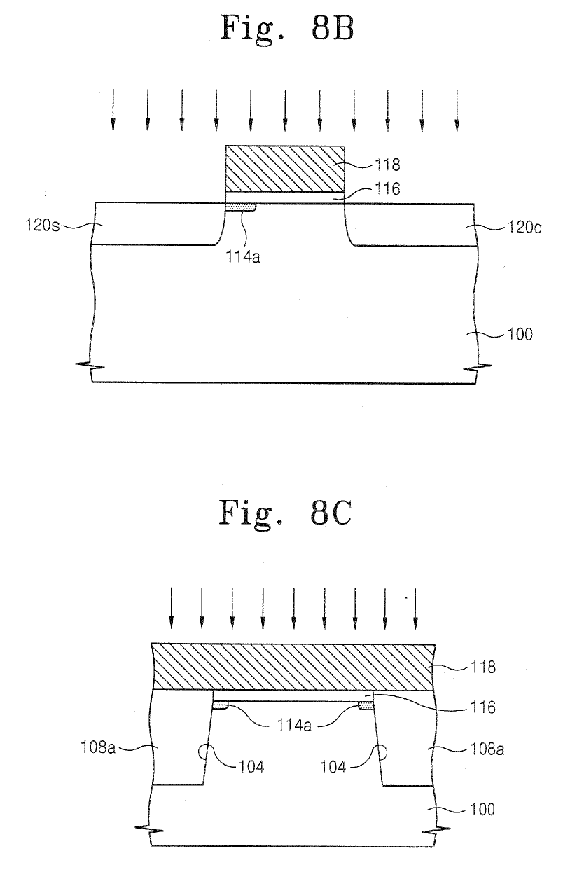

Subsequently, referring to FIGS. 7A to 7C, and 8A to 8C, the photoresist layer 110 is removed from the semiconductor substrate 100. After removing the photoresist layer 110, a rinsing process is performed to expose the surface of the active region 106. Through the rinsing process, residues of the photoresist layer 110, or the like, may be removed. Moreover, the buffer oxide layer for ion implantation may be removed through the rinsing process.

Thereafter, the gate insulating layer 116 and a gate conductive layer are formed on the semiconductor substrate 100 in sequence. The gate conductive layer is patterned to form the gate electrode 118 which crosses over the active region 106. The gate electrode 118 covers a portion of the channel doped layer 114. Therefore, the other portion of the channel doped layer 114 may be exposed to one side of the gate electrode 118. Furthermore, the gate electrode 118 may cover a portion of the active region 106 where the channel doped layer 114 is not formed.

Second conductive impurity ions are implanted using the gate electrode 118 as a mask so as to form the source region 120s and the drain region 120d on both sides of the gate electrode 118. At this time, the channel region is defined under the gate electrode 118, wherein the channel region is provided with the first region 114a and the second region.

The portion of the channel doped layer 114 covered with the gate electrode 118 corresponds to the first region 114a, and the region under the gate electrode 118 where the channel doped layer 114 is not formed corresponds to the second region. The channel doped layer 114 has high impurity concentration which is higher than that of the active region 106 where the channel doped layer 114 is not formed. That is, the impurity concentration of the first region 114a is higher than that of the second region.

The first region 114a is formed such that it is spaced apart from the drain region 120d. By forming the gate electrode 118 wider than the first region 114a, the first region 114a may be spaced apart from the drain region 120d. Meanwhile, the first region 114a may be in contact with the source region 120s because the gate electrode 118 covers only a portion of the channel doped layer 114. The other portion of the channel doped layer 114 exposed to one side of the gate electrode 118 becomes part of the source region 120s when the second conductive impurity ions are implanted.

Through the above methods, it is possible to implement the high-voltage transistor illustrated in FIGS. 2A to 2C.

Meanwhile, a method of forming the high-voltage transistor of FIGS. 3A and 3B is very similar to the above method. However, unlike the above method, the gate electrode 118 is formed to completely cover the channel doped layer 114 in the high-voltage transistor of FIGS. 3A and 3B. Herein, both the sidewalls of the gate electrode 118 should be spaced apart from the channel doped layer 114. Therefore, it is possible to implement the first region 114a′ of FIGS. 3A and 3B spaced apart from the source and drain regions 120s and 120d. The first region 114a′ of FIGS. 3A and 3B corresponds to the channel doped layer 114, which is completely covered with the gate electrode 118. Herein, the distance between a first sidewall of the gate electrode 118 and the channel doped layer 114 under the gate electrode 118 is defined as a first distance, where the first sidewall of the gate electrode 118 is adjacent to the source region 120s. In addition, the distance between a second sidewall of the gate electrode 118 and the channel doped layer 114 under the gate electrode 118 is defined as a second distance, where the second sidewall of the gate electrode 118 is adjacent to the drain region 120d. At this time, the gate electrode 118 may be aligned with the channel doped layer 114 such that the first distance is shorter than the second distance. Accordingly, in the high-voltage transistor of FIGS. 3A and 3B, the distance between the first region 114a′ and the source region 120s may be shorter than the distance between the first region 114a′ and the drain region 120d.

As described above, according to the present invention, the channel region under the gate electrode includes the first region and the second region. The first region has an impurity concentration that is higher than that of the second region. In addition, the first region is in contact with the isolation layer. Accordingly, the pathway of the leakage current between the source and the drain is blocked in virtue of the first region. As a result, it is possible to minimize the leakage current between the source and the drain when the high-voltage transistor is turned off.

Furthermore, the first region is formed such that it is spaced apart from the drain region. Therefore, the drain region is in contact with the lightly doped second region, and it is possible to minimize the junction leakage current between the drain region and the channel region even though the high voltage is applied to the drain region.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A high-voltage transistor comprising:
an isolation layer formed at a semiconductor substrate, to define an active region;
a gate electrode formed over the active region;
a source region and a drain region formed in the active region on opposite sides of the gate electrode, respectively; and
a channel region defined under the gate electrode, the channel region including a first region and a second region, wherein an impurity concentration of the first region is higher than an impurity concentration of the second region, and wherein the first region is in contact with the isolation layer.

2. The high-voltage transistor of claim 1, wherein the first region is spaced apart from the drain region.

3. The high-voltage transistor of claim 2, wherein the first region is in contact with the source region.

4. The high-voltage transistor of claim 3, wherein a back bias voltage, a source voltage, and a drain voltage are applied to the channel region, the source region, and the drain region, respectively, a voltage difference between the drain voltage and the back bias voltage being higher than a voltage difference between the source voltage and the back bias voltage.

5. The high-voltage transistor of claim 2, wherein the first region is spaced apart from the source region.

6. The high-voltage transistor of claim 5, wherein the distance between the first region and the source region is shorter than the distance between the first region and the drain region.

7. The high-voltage transistor of claim 1, wherein the channel region includes a pair of the first regions which are spaced apart from each other, the pair of the first regions being in contact with the isolation layer on both sides of the channel region, respectively.

8. The high-voltage transistor of claim 1, wherein the channel region is doped with a first conductive impurity, and the source and drain regions are doped with a second conductive impurity.

9. A high-voltage transistor comprising:
an isolation layer formed at a semiconductor substrate to define an active region;
a gate electrode crossing over the active region;
a gate insulating layer interposed between the gate electrode and the active region;
a source region and a drain region formed in the active region at opposite sides of the gate electrode, respectively; and
a channel region defined under the gate electrode, the channel region including at least one first region and a second region, wherein the at least one first region has a higher impurity concentration than that of the second region, and wherein the at least one first region is in contact with the isolation.

10. The high-voltage transistor of claim 9, wherein the channel region includes two first regions spaced apart from each other and in contact with the isolation layer on each side of the channel region, respectively.

11. The high-voltage transistor of claim 10, wherein the first regions are in contact with the source region and are spaced apart from the drain region.

12. The high-voltage transistor of claim 10, wherein the first regions are spaced apart from the source region and are spaced apart from the drain region, a distance between the first regions and the source region being less than a distance between the first regions and the drain region.

13. A method of forming a high-voltage transistor, the method comprising:
forming an isolation layer and a channel doped layer to be in contact with each other, wherein the isolation layer is formed to define an active region at a semiconductor substrate doped with first conductive impurities, and wherein the channel doped layer is formed by selectively implanting first conductive impurity ions such that the channel doped layer has a higher impurity concentration than the substrate;
forming a gate insulating layer on the active region;
forming a gate electrode over the active region on the gate insulating layer, the gate electrode covering the channel doped layer; and
forming a source region and a drain region by implanting second conductive impurity ions using the gate electrode as a mask,
wherein a channel region under the gate electrode includes a first region corresponding to the channel doped layer under the gate electrode, and a second region corresponding to the region under the gate electrode where the channel doped layer is not formed.

14. The method of claim 13, wherein a pair of channel doped layers are formed in the active region, the pair of the channel doped layers spaced apart from each other and in contact with the isolation layer on both sides of the active region, respectively.

15. The method of claim 13, wherein the first region is spaced apart from the drain region.

16. The method of claim 15, wherein the first region is in contact with the source region.

17. The method of claim 15, wherein the source region is spaced apart from the first region.

18. The method of claim 17, wherein the distance between the source region and the first region is shorter than the distance between the drain region and the second region.

19. The method of claim 13, wherein forming the isolating layer and the channel doped layer comprises:
forming the isolation layer at the semiconductor substrate to define the active region; and
after forming the isolation layer, selectively implanting the first conductive impurity ions into the active region to form the channel doped layer.

20. The method of claim 13, wherein forming the isolating layer and the channel doped layer comprises:
forming the channel doped layer by selectively implanting the first impurity ions into the semiconductor substrate; and
after forming the channel doped layer, forming the isolation layer at the semiconductor substrate having the channel doped layer to define the active region.
